(19) United States
(12) Patent Application Publication
(10) Pub. No.: US 2014/0197453 A1
(43) Pub. Date: Jul. 17, 2014

(54) IMAGE SENSOR WITH LAYERS OF DIRECT BAND GAP SEMICONDUCTORS HAVING DIFFERENT BAND GAP ENERGIES

(71) Applicant: BROADCOM CORPORATION, Irvine, CA (US)

(72) Inventor: Ilya Blayvas, Holon (IL)

(73) Assignee: Broadcom Corporation, Irvine, CA (US)

(21) Appl. No.: 13/753,860

(22) Filed: Jan. 30, 2013

Related U.S. Application Data
(60) Provisional application No. 61/752,595, filed on Jan. 15, 2013.

(51) Int. Cl. H01L 27/146

(52) U.S. Cl. CPC H01L 27/14645
USPC 257/184; 438/94

(57) ABSTRACT

Embodiments of an exemplary image sensor structure of the present disclosure contains at least two different layers of band gap semiconductors, where each upper layer of the different layers has a different band gap than a lower layer. For such an image sensor structure, the upper layer has a greater band gap than any layer positioned below the upper layer including the lower layer.

### CROSS-REFERENCE TO RELATED APPLICATIONS

This application claims the benefit of a copending U.S. provisional application entitled, “Image Sensor With Layers of Direct Band Gap Semiconductors Having Different Band Gap Energies,” having Ser. No. 61/752,595, filed Jan. 15, 2013, which is entirely incorporated herein by reference.

### BACKGROUND

In conventional color digital imaging, a pixel color value is detected due to a color mosaic deposited on a surface of an image sensor. This color mosaic filter is known in the art as the Bayer mosaic. The image sensor is sensitive throughout the color spectrum, while the color mosaic transfers, for each pixel, the spectrum of required color and absorbs the rest of the spectrum. This approach suffers from several major shortcomings.

First, about 70% of the light is absorbed in the color filters (e.g., red filter absorbs green and blue waves, etc.), which decreases the sensor sensitivity in the low light and increases the sensor noise. Second, different colors are detected in different pixels of the image sensor, and therefore, different points of the captured image. Thus, the spatial resolution of the image sensor is reduced, leading to errant sampling of fine color structures and aliasing artifacts along the edges.

Further, to decrease the phenomenon of color aliasing, an optical low-pass filter (OLPF) is usually added in front of the image sensor. The OLPF filter partially blurs the image, decreasing the color aliasing phenomenon, while simultaneously decreasing the image resolution. Furthermore, the OLPF is usually based on polarizing properties of optical birefringence materials and fails to properly work under the conditions of polarized illumination, thereby limiting use of polarization techniques and degrading the image quality under the polarized illumination. Lastly, colored light filtered by a corresponding color filter is scattered and absorbed within neighbor pixels, decreasing value of the appropriate pixel, and contributing to an errant reading of the color value for the pixel. This is generally referred as color cross-talk.

An alternative approach further suggested in the prior art is to use the layered structure of the silicon sensor and the physical property of silicon in which the absorption of blue wavelengths is stronger than the absorption of red wavelengths. However, this approach suffers from inevitable strong color cross-talk between the different color pixels.

### BRIEF DESCRIPTION OF THE DRAWINGS

FIG. 1 is a schematic diagram showing an image sensor using a silicon layered structure.

FIG. 2 is a schematic diagram showing the spectral sensitivity of different layers of silicon for the image sensor of FIG. 1.

FIG. 3 is a schematic diagram showing a stack-layered structure of a direct band gap semiconductor image sensor in accordance with embodiments of the present disclosure.

FIGS. 4A-4B are schematic diagrams showing the spectral sensitivities of the image sensor of FIG. 3 in accordance with the present disclosure.

FIGS. 5-6 are flow chart diagrams illustrating exemplary embodiments of a method for implementing a color image sensor in accordance with the present disclosure.

FIG. 7 is a block diagram of an exemplary imaging system in accordance with an embodiment of the present disclosure.

### DETAILED DESCRIPTION

This disclosure provides systems and methods for implementing an image sensor using semiconductor structures. Instead of using different widths diode structures of the same indirect band gap silicon (Si) sensor, as proposed in the prior art, causing significant color cross-talk, embodiments of the present disclosure utilize layers of direct band gap semiconductors with different band gaps. Such a resulting structure has multiple advantages over the prior art.

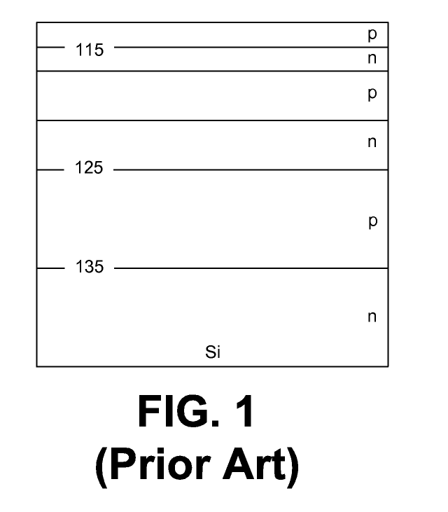

Consider an alternative design of an image sensor proposed by Hopper, et al. in U.S. Pat. No. 7,105,373. The disclosed techniques in U.S. Pat. No. 7,105,373 are based on the fact that absorption length of light in Si depends on the wavelength: blue wavelengths having the strongest absorption (7×10⁴ cm⁻¹ for 400 nm wavelength, corresponding to 130 nm typical penetration thickness), green wavelengths having medium absorption (7×10³ cm⁻¹ for 550 nm wavelength, corresponding to 1.30 μm typical penetration thickness), and the red wavelengths having the weakest absorption (2×10³ cm⁻¹ for 700 nm wavelength, corresponding to 5 μm typical penetration depth). Utilizing this principle, Hopper, et al. in U.S. Pat. No. 7,105,373 suggests a layered structure of 3 photodiodes, with the thinnest diode 115 on top, the diode 125 having average thickness in the middle, and diode 135 being the thickest in the bottom of the structure, as shown in FIG. 1. Therefore, the thinnest topmost diode 115 is theoretically more sensitive to the blue wavelengths (since they have the highest absorption coefficient), while the thickest bottom lying diode 135 is more sensitive to the red wavelengths (since most of blue and greed waves are absorbed in the higher layers).

However, in reality, this structure has its own limitations. For the typical division of color spectrum into blue (400-480 nm), green (480-580 nm), and red (580-700 nm) bands, the centers of the bands fall at 440 nm, 530 nm, and 640 nm respectively, with corresponding absorption coefficient of 2×10⁴ cm⁻¹ and absorption thickness of 0.5 μm for mid-range blue (440 nm wavelength); absorption coefficient of 8×10³ cm⁻¹ and absorption thickness of 1.25 μm for mid-range green (530 nm wavelength); and absorption coefficient of 3.3×10³ cm⁻¹ and absorption thickness of 3 μm for mid-range red (640 nm wavelength) bands. Practically, this means that a significant portion of blue rays is absorbed in the region counting for green and even red, and the same for red rays and especially green rays. A person skilled in the art can estimate theoretically that there will be very high inevitable color cross-talk of at least 40% between the different colors, since a blue absorption length of 0.5 μm constitutes 40% of a 1.25 μm green absorption length, which in turn constitutes about 42% of a 3 μm red absorption length. This severe color cross-talk increases the sensor color noise and decreases the color accuracy and sensitivity, degrading general sensor efficiency and image quality.

It is further noted that the light sensitivity of a semiconductor image sensor is due to the process of generating an electron and a hole pair by an absorbed photon. The minimal energy required to generate such a pair is called a band gap energy of the semiconductor, and it varies for different types and compositions of semiconductors. Accordingly, semiconductors are divided into two groups by respective mechanisms of photon absorption: (1) direct band gap semiconductors, where all the energy of absorbed photon goes into generation of an electron and hole pair (e.g., GaAS, and other group 3-5 semiconductors); and (2) indirect band gap semiconductors (e.g., Si, which is used in many, if not most, prior art image sensors), where the momentums of electron and hole are different, and therefore a vibration quant (phonon) is also generated in the photon absorption process due to the conservation of the moment.

Both direct and indirect band gap semiconductor sensors are sensitive to the photons with the energies exceeding the band gap energy, which can generate the electron-hole pair. Additionally, direct and indirect band gap semiconductors are transparent to the photons with energies below the band gap. However, the absorption coefficient behavior for the photons above the band gap is different. In the indirect band gap semiconductor, part of the photon energy is required to generate a phonon; therefore, the absorption coefficient of the indirect band gap semiconductors is very low near the edge of the band gap, and is known in the art to be described by:

$$∝ ( E ) = {∝}_{0} {( \frac{E - {E}_{g}}{{E}_{g}} )}^{2} , \qquad ( 1 )$$

where E is the energy of the photon, and E_{g} is the band gap energy.

However, the absorption coefficient of the direct band gap semiconductors is known in the art to be described by:

$$∝ ( E ) = {∝}_{0} \sqrt{\frac{E - {E}_{g}}{{E}_{g}}} , \qquad ( 2 )$$

which is a sharply rising function above the band gap energy. Moreover, by varying the chemical composition of the direct band gap semiconductor, one can adjust the band gap energy to correspond to the desired wavelength. Therefore, the direct band gap semiconductor allows an efficient solution for the color image sensor, where the color sensitivity is separated due to varying energy band gaps of the corresponding layers, as described below. Further, different layers of the direct band gap semiconductors (having different band gaps) can implement a photo-sensitive structure based on electric conductivity increasing with generation of electron-hole pairs by absorption of photons with energy exceeding the band gap energy. Therefore, an area of the semiconductor layers may be subdivided into specific regions corresponding to sensor pixels, in accordance with embodiments of the present disclosure.

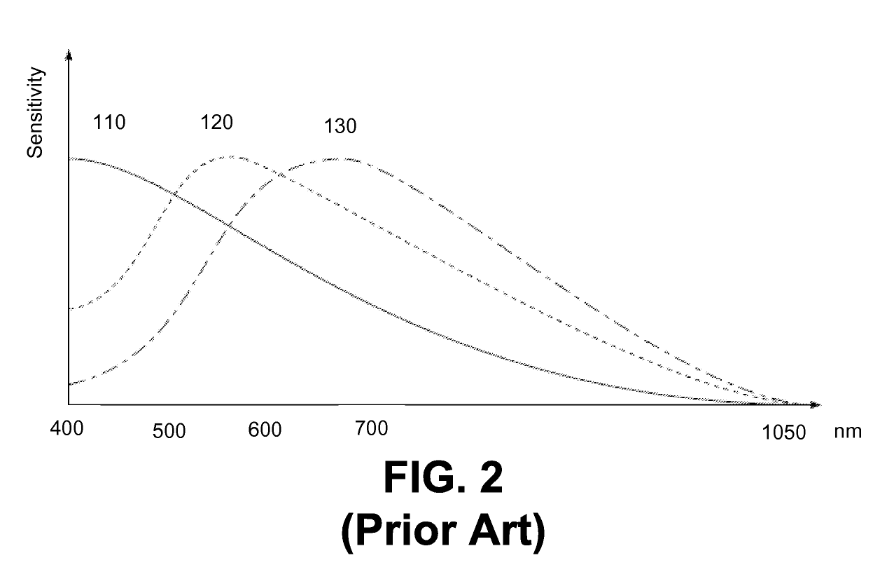

For further illustration, FIG. 2 shows the plots of absorption coefficient for Si (indirect band gap). In the figure, plot 110 shows the sensitivity of the thinnest diode 115 in a stack structure (represented in FIG. 1). As shown in FIG. 2, diode 115 is most sensitive for short wavelengths or the blue part of the spectrum which is 500 nm and below. Plot 120 shows the sensitivity of the middle diode 125 in the stack (represented in FIG. 1). As shown in FIG. 2, diode 125 is most sensitive for the green part of the spectrum which is in the range 500 nm-600 nm. Correspondingly, plot 130 shows the sensitivity of the bottom diode 135 in the stack (represented in FIG. 1). As shown in FIG. 2, diode 135 is most sensitive for the red part of the spectrum which is in the range 600 nm and greater (e.g., 600 nm-700 nm).

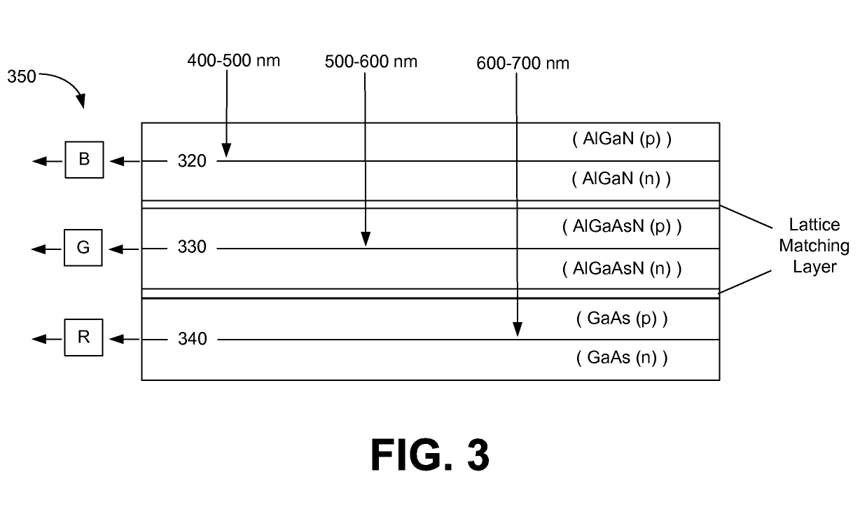

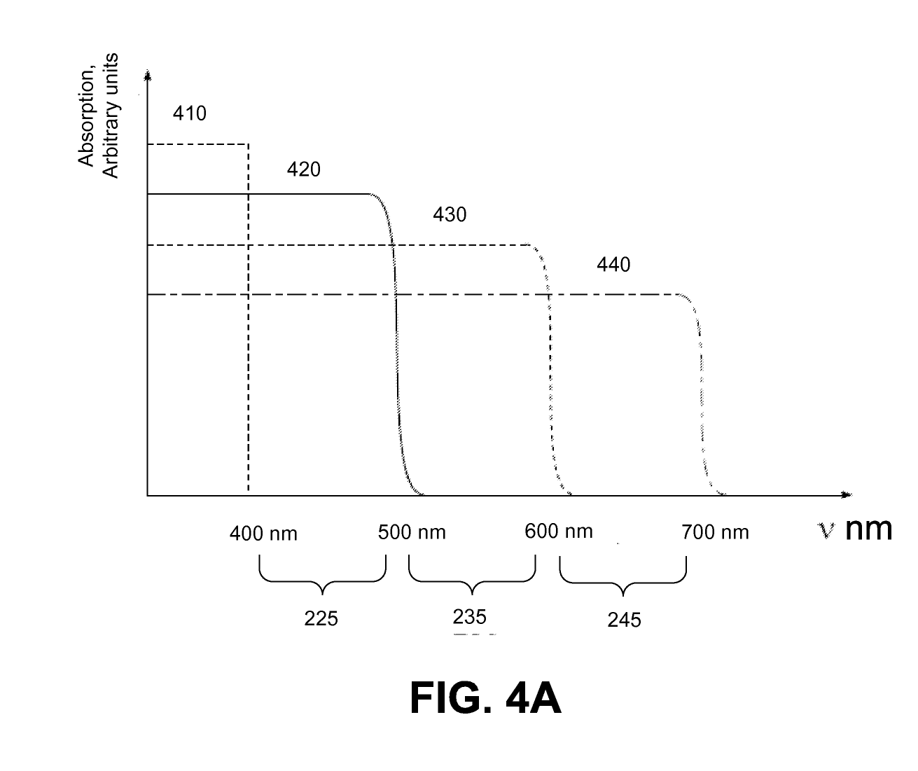

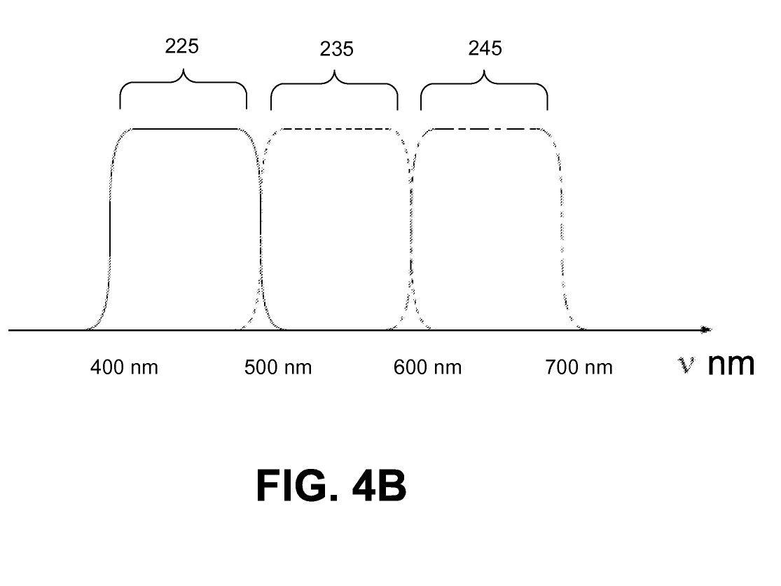

In accordance with embodiments of the present disclosure, an exemplary stack-layered structure of a direct band gap semiconductor image sensor is depicted in FIG. 3. Further, FIG. 4A shows the absorption curves for three layers of such a direct band gap semiconductor (420, 430, and 440) as well as ultraviolet (UV) blocking filter (410). The horizontal axis shows the light wavelength, with the region 400-700 nm being the visible spectrum, and the vertical axis shows the absorption coefficient.

Semiconductor upper layer 420 has a band gap energy of 2.48 eV corresponding to 500 nm wavelength and, therefore, has a photo-sensitivity for all the wavelengths below 500 nm, and transmits all the wavelengths above 500 nm. In one embodiment, a UV filter of an optical system (employing the stack structure for an image sensor) cuts off wavelengths below 400 nm. Therefore, an effective sensitivity band of upper layer 420 is within 400 nm-500 nm range, corresponding to the blue sub-band 225.

In some embodiments, semiconductor middle layer 430 has a band gap energy of 2.07 eV corresponding to 600 nm wavelength. Accordingly, the middle layer 430 has a photo-sensitivity for wavelengths below 600 nm and transmits all the wavelengths above 600 nm. However, since the wavelengths shorter than 500 nm are already absorbed by the upper layer 420, an effective sensitivity band of middle layer 430 will be 500-600 nm, corresponding to the green sub-band 235.

Finally, lower layer 440 has a band gap energy of 1.77 eV corresponding to 700 nm wavelength. Correspondingly, lower layer 440 has a photo-sensitivity for the wavelengths below 700 nm and transmits all the wavelengths above 700 nm. However, since the wavelengths shorter than 600 nm are already absorbed by UV filter and the layers 430 and 440, in one embodiment, an effective sensitivity band of lower layer 440 is 600-700 nm, corresponding to the red sub-band 245.

Thus, referring to FIG. 4B, upper layer 420 is responsive to the blue band 225, middle layer 430 is responsive to the green band 235, and lower layer 440 is responsive to the red band 245. Moreover, since each layer, on one hand, is completely transparent for the photons with energies below its band gap; and, on the other hand, the thickness of the layer can be made substantial for high efficiency of absorption within the band, very high quantum efficiency and color separation can be achieved with this stack structure, since it does not suffer from limitations of prior art technologies described above.

Moreover, the sub-bands of 400-500 nm, 500-600 nm, and 600-700 nm are given as a non-limiting illustration only. The specific band gap energies and the quantity of layers can be chosen arbitrarily according to the specific engineering requirements of a designed image sensor as understood by one of ordinary skill in the art.

In accordance with the present disclosure, the transparency of a direct band gap semiconductor below the band gap energy and sharply rising absorption above the band gap energy provides for a layered or stacked structure for an image sensor of selective absorption within pre-designed light bandwidths, as illustrated in FIG. 3. Here, an upper layer 320 of a direct band gap semiconductor diode is positioned upon a middle layer 330 of a direct band gap semiconductor diode (with a lattice matching layer between the two). The band gap energy of an upper layer is greater than the band gap energy of the layer directly below it. Accordingly, the band gap energy of upper layer 320 is greater than the band gap energy of middle layer 330. Correspondingly, the band gap energy of middle layer 330 is greater than the band gap energy of lower layer 340 (which is positioned below layer 330). In various embodiments, additional layers are contemplated, such as a layer positioned above the upper layer 320 (e.g., for absorption of ultraviolet wavelength rays) and/or a layer positioned below the lower layer 340 (e.g., for absorption of infrared wavelength rays).

Accordingly, instead of using different widths diode structures of the same indirect band gap (Si) sensor, as proposed in the prior art, and resulting in significant color cross-talk, embodiments of the present disclosure utilize layers of direct band gap semiconductors with different band gap energies to build a color image sensor, based on the different physical properties. For various embodiments, the different layers of the direct band gap semiconductor image sensor are composed as an arbitrary chemical composition of a direct band gap semiconductor.

As such, the most popular direct band gap semiconductors are group 3-5 semiconductors composed of chemical elements Al, Ga, In, B, N, P, As, Sb according to the formula: Alₓ₁Gaₓ₂Inₓ₃Bₓ₄N_{y1}P_{y2}As_{y3} Sb_{y4}, where x1, x2, x3, x4, y1, y2, y3, y4 are the molar fractions of the elements (x1+x2+x3+x4=y1+y2+y3+y4=1). To illustrate, FIG. 3 shows a top layer being of AlGaN, a middle layer being of AlGaAsN, and a bottom or lower layer being of GaAs semiconductor compositions. However, embodiments are not meant to be limited to the above composition of a direct band gap semiconductor and can use any known alternative type of direct band gap semiconductor, including the 2-6 type of semiconductors.

In accordance with the present disclosure, photo-sensing is based on the generation of an electron-hole pair by absorption of a photon with the energy exceeding the band gap energy. Various pixel light-sensing architectures can be used to sense, digitize, and read-out pixel values, as is understood by one of ordinary skill in the art. In various embodiments, an exemplary photo-sensing element may be a photo-resistor (where photo-generated carriers decrease the resistivity), a reversely biased photo-diode (where photo-generated carriers participate in the reverse current), photo-transistor (where conductivity increases with illumination), or other type of sensing element based on photocurrent. Accordingly, various pixel read-out architectures known in the art can be used in accordance with the present disclosure. As such, embodiments may incorporate circuitry 350 (FIG. 3) enabling measuring and reading out of light energy within a controlled time interval, separately from each layer corresponding to separate sub-band of a color spectrum, among other possibilities. Therefore, an area of the semiconductor layers can be subdivided into specific regions corresponding to sensor pixels, where a photo-sensitive structure layer of each sensor pixel is connected to the circuitry.

For illustration, the band gap energies of these semiconductors varies from approximately 1.42 eV for GaAs, corresponding to wavelength of 870 nm to 6.2 eV for AlN corresponding to wavelength of 200 nm. Group 3-5 direct band gap semiconductors (e.g., Ga As, GaAlAs, GaN, etc.) are excellent photodetectors at photon energies at and above their respective band gap energy (e.g., wavelengths at or shorter than the band gap energy). At the same time, group 3-5 direct band gap semiconductors are transparent to wavelengths longer than the respective band gap energy (e.g., photons with energies below the band gap).

Various embodiments may be characterized by the design and manufacture of a color image sensor containing plural layers (e.g., 10 layers, as a non-limiting example) of direct band gap semiconductors, of different ever-decreasing band gaps from the surface towards the deeper layers. Such structures can divide and measure the optical spectrum within the energy sub bands defined by the band gap energies, according to the principles described above.

In an alternative embodiment, a similarly stacked or layered structure may be used with highly efficient solar cells. In general, for solar cells, the photon absorbed in the depletion region of the diode's p-n junction generates an electron-hole pair, which is dragged apart by the internal field of the junction, and results in photo-current. Accordingly, solar cells suffer from low converting efficiency, since all the photons with energies below the band gap are going through the cell without interaction, and wasted completely, while the photons with the arbitrary high energies (Ehv) above the band gap energy (Ehv>Eg) normally produce only one electron-hole pair, generating the energy of Eg. Thus, all the extra energy is wasted.

In accordance with the present disclosure, an exemplary solar cell is built as multiple layers of diodes in direct band gap semiconductors with band gaps starting from the highest energy, and gradually decreasing towards the lowest band gap energies. Such a structure utilizes each photon with its highest possible efficiency. For example, in one embodiment, a solar cell structure includes an upper layer of AlN with a band gap energy of 6.2 eV for absorption in the UV band; middle levels of Al₁₋ₓGaₓAsₓN₁₋ₓ with decreasing concentrations of Al and N and proportionally increasing concentrations of Ga and As with gradually decreasing band gap energies toward the 1.424 eV of GaAs, and further lower layers of In₁₋ₓGaₓAsₓSb₁₋ₓ with gradually decreasing band gap energies toward 0.17 eV of pure InSb.

Thus, the UV band with Ehv>6.2 eV will be absorbed in the upper layer, and photons with energies below 6.2 eV will go through the upper layer unabsorbed. If the band gap energy of the next layer is designed with Eg=6.0 V, then only the photons with 6.2>Ehv>6.0 V will be absorbed by the next layer, with an average conversion efficiency of 6.1 eV/6.0 eV>98%. Similarly, by designing each lower level with gradually decreasing band gap energies, with Eg(n)=Eg(n−1)*_{η}, the photons with the average energy of Eg(n−1)+Eg(n) will be converted into the energy of Eg(n) with average efficiency (1+η)/2. Practically, this means that such a structure containing 20 different layers, starting from 200 nm 6.2 eV towards 200 nm 0.62 eV, with Eg(n)=0.9*Eg(n−1), can have conversion efficiency of 95% for the entire spectrum of solar energy reaching the earth through the atmosphere (which is a major breakthrough in comparison to best state-of the art reported results of 42% for 2012).

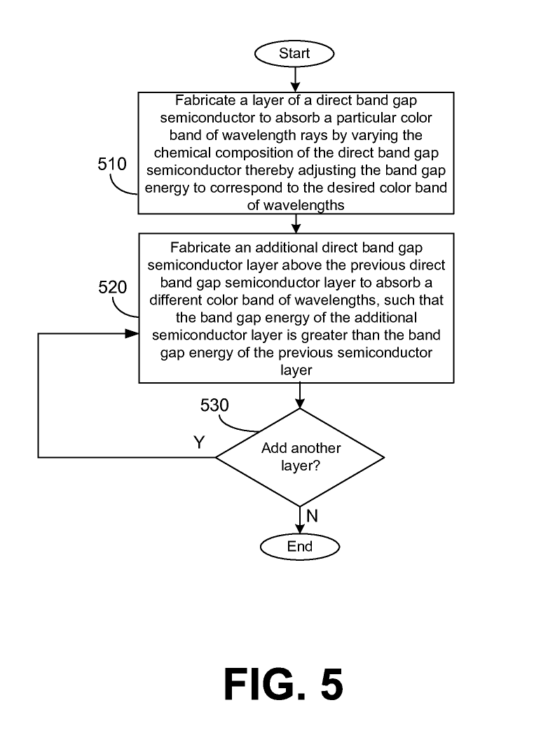

Referring next to FIG. 5, shown is a flow chart diagram that provides one example of a method for implementing a color image sensor in accordance with the present disclosure. The exemplary method begins with fabricating (510) a semiconductor layer (e.g. via growing by epitaxy), where the semiconductor layer constitutes a direct band gap semiconductor material. Next, an additional direct band gap semiconductor layer is fabricated (520) above the previous semiconductor layer, such that the band gap energy of the additional semiconductor layer is greater than the band gap energy of the previous semiconductor layer. Therefore, each resulting direct band gap semiconductor layer positioned above a lower direct band gap semiconductor layer of the color image sensor absorbs an effective sensitivity band of light rays with wavelengths less than the band of light rays above the lower layer. For example, referring to FIG. 4A, the middle layer 430 has a photo-sensitivity for wavelengths below 600 nm and transmits all the wavelengths above 600 nm. However, since the wavelengths shorter than 500 nm are already absorbed by the upper layer 420, an effective sensitivity band of middle layer 430 will be 500-600 nm, corresponding to the green sub-band. Additionally, by varying the chemical composition of the direct band gap semiconductor, one can adjust the band gap energy to correspond to the desired band of wavelengths. Accordingly, additional direct band gap semiconductor layers may be added (530) until a desired number of layers or diodes are reached for the color image sensor.

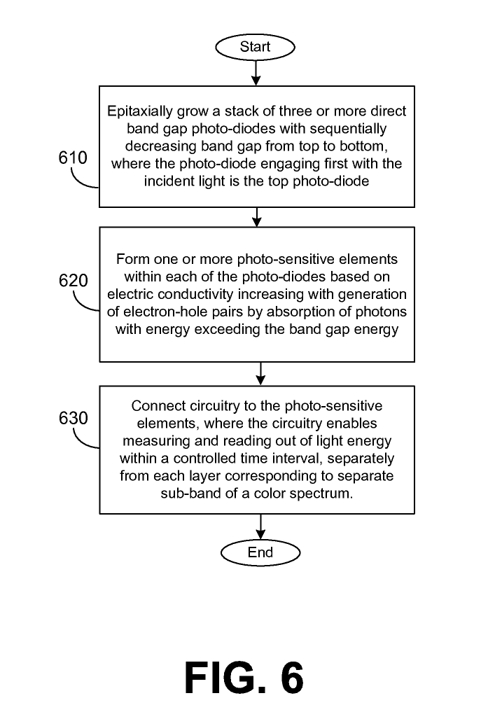

Next, FIG. 6 shows a flow chart diagram that provides an additional example of a method for implementing a color image sensor in accordance with the present disclosure. The method begins with epitaxially growing (610) a stack of three or more direct band gap photo-diodes with sequentially decreasing band gap from top to bottom, where the photo-diode engaging first with the incident light is the top photo-diode. Correspondingly, one or more photo-sensitive elements are formed (620) within each of the photo-diodes based on electric conductivity increasing with generation of electron-hole pairs by absorption of photons with energy exceeding the band gap energy. Accordingly, circuitry is connected (630) to the photo-sensitive elements, where the circuitry enables measuring and reading out of light energy within a controlled time interval, separately from each layer corresponding to separate sub-band of a color spectrum.

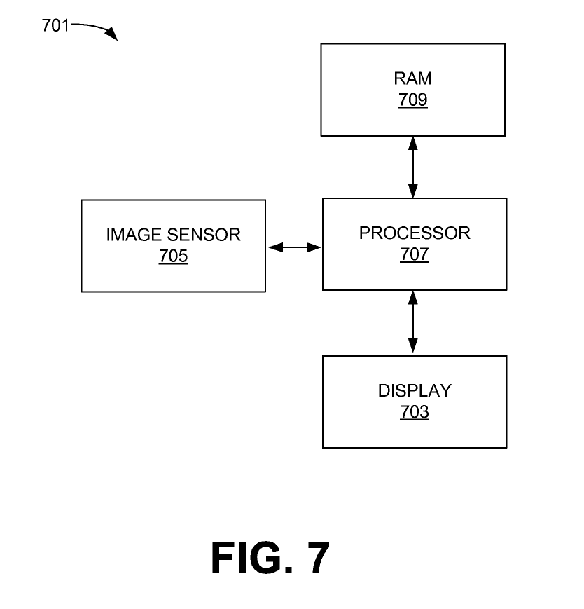

FIG. 7 is a block diagram of an exemplary imaging system, in connection with an embodiment of the present disclosure. Referring to FIG. 7, there is shown an imaging system 700 comprising a communication device 701 with a display screen 703, an image sensor 705, and a processor or processing block 707. The communication device 701 may comprise suitable circuitry, logic and/or code for communicating over a cellular network and capturing, processing, storing and/or displaying an image generated by the image sensor 705. The display screen 703 may comprise suitable circuitry, logic and/or code for displaying an image generated by the image sensor 705 and the processor 707. The image sensor 705 may comprise a multi-megapixel CMOS or related technology sensor array that may be enabled to detect a visual image and generate digital data representing that image, as discussed previously.

The processor 707 may comprise suitable circuitry, logic and/or code for processing the image data received from the image sensor 705. The processing steps, or image sensor pipeline (ISP), performed by the processor 707 may comprise, for example, filtering, demosaic, lens shading correction, defective pixel correction, white balance, image compensation, color transformation, and post filtering.

In operation, the image sensor 705 in the communication device 701 may perform an image capture. The image data may be transferred to the processor 707. The data may then be subjected to processing. The processing may comprise filtering, white balance, image compensation, for example. The data may then be compressed, stored on RAM 709, and/or displayed on the display screen 703.

RAM 709 may comprise suitable circuitry, logic and/or code for storing data. The processor 707 may comprise suitable circuitry, logic and/or code that may be enabled to send control signals to and receive data from the image sensor 705 and the RAM 709. The processor 707 may also be enabled to communicate data to the display 703.

In operation, the image sensor 705 may generate image data from an image capture and transfer this data to the processor 707. The processor 707 may provide clock and control signals for synchronizing the data transfer from the image sensor 705. The data may be communicated to the processor 707 for processing in the ISP. The data may be communicated to the display 703 for viewing and/or may be compressed by the processor 707 and stored in the RAM 709. The processor 705 may communicate address data to the RAM 709 to determine where to read or write data in the RAM 709.

It should be emphasized that the above-described embodiments of the present disclosure are merely possible examples of implementations, merely set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure.

Therefore, having thus described various embodiments, at least the following is claimed:

1. An image sensor structure comprising:
at least two different layers of direct band gap semiconductors positioned in a stack, each upper layer of the different layers having a different band gap than a lower layer,
wherein the upper layer has a greater band gap than any layer positioned below the upper layer including the lower layer,
wherein the lower layer encounters light to be sensed after the light passes through the upper layer.

2. The image sensor structure of claim 1, wherein the different layers are composed as an arbitrary chemical composition of a direct band gap semiconductor.

3. The image sensor structure of claim 1, wherein the different layers are composed as Alₓ₁Gaₓ₂Inₓ₃Bₓ₄N_{y1}P_{y2}As_{y3} Sb_{y4}, where x1, x2, x3, x4, y1, y2, y3, y4 are molar fractions of elements such that x1+x2+x3+x4=y1+y2+y3+y4=1.

4. The image sensor structure of claim 3, wherein the band gap of the different layers varies from approximately 1.42 eV for GaAs, corresponding to a wavelength of 870 nm, to approximately 6.2 eV for AlN, corresponding to a wavelength of 200 nm.

5. The image sensor of claim 1, further comprising circuitry enabling measuring and reading out of light energy within a controlled time interval, separately from each layer corresponding to a separate sub-band of a color spectrum.

6. The image sensor structure of claim 5, wherein the different layers comprise three layers corresponding to photo-sensitivity in red, green, and blue sub-bands of a color spectrum.

7. The image sensor structure of claim 6, wherein the different layers further comprise at least one additional layer corresponding to photo-sensitivity in an ultraviolet sub-band, infrared sub-band, or both infrared and ultraviolet sub-bands.

8. The image sensor structure of claim 1, where the semiconductor layers with different band gaps implement a photo-sensitive structure based on electric conductivity increasing with generation of electron-hole pairs by absorption of photons with energy exceeding the band gap energy.

9. The image sensor structure of claim 8, where an area of the semiconductor layers is subdivided into specific regions corresponding to sensor pixels.

10. The image sensor structure of claim 9, further comprising circuitry enabling measuring and reading out of light energy within a controlled time interval, separately from each layer corresponding to separate sub-band of a color spectrum, wherein each photo-sensitive structure layer of each sensor pixel is connected to the circuitry.

11. A method comprising:
epitaxially growing a stack of three or more direct band gap photo-diodes with sequentially decreasing band gap from top to bottom, where the photo-diode engaging first with the incident light is the top photo-diode;
forming one or more photo-sensitive elements within each of the photo-diodes based on electric conductivity increasing with generation of electron-hole pairs by absorption of photons with energy exceeding the band gap energy; and
connecting circuitry enabling measuring and reading out of light energy within a controlled time interval, separately from each photo-diode corresponding to separate sub-band of a color spectrum, wherein each photo-sensitive element is connected to the circuitry.

12. The method of claim 11, where the photo-diodes are composed as an arbitrary chemical composition of a direct band gap semiconductor.

13. The method of claim 11, wherein the photo-diodes are composed as Alₓ₁Gaₓ₂Inₓ₃Bₓ₄N_{y1}P_{y2}As_{y3}Sb_{y4}, where x1, x2, x3, x4, y1, y2, y3, y4 are molar fractions of elements such that x1+x2+x3+x4=y1+y2+y3+y4=1.

14. The method of claim 13, wherein the band gap of the different photo-diodes varies from approximately 1.42 eV for GaAs, corresponding to a wavelength of 870 nm, to approximately 6.2 eV for AlN, corresponding to a wavelength of 200 nm.

15. The method of claim 11, wherein the different photo-diodes comprise three photo-diodes corresponding to photo-sensitivity in red, green, and blue sub-bands of the color spectrum.

16. The method of claim 15, wherein the different photo-diodes further comprise at least one additional photo-diode corresponding to photo-sensitivity in an ultraviolet sub-band, infrared sub-band, or both infrared and ultraviolet sub-bands.

17. The method of claim 11, further comprising subdividing an area of the photo-diodes into specific regions corresponding to sensor pixels.

18. The method of claim 11, wherein each photo-diode absorbs light rays corresponding to a particular color band without color mixing.

19. A color image sensor structure, comprising:
a layered structure having selective absorption within pre-designed light bandwidths, the layer structure comprising:
an upper layer of a first direct band gap semiconductor diode;
a middle layer of a second direct band gap semiconductor diode; and
a lower layer of a third direct band gap semiconductor diode, wherein a band gap energy of the upper layer is greater than a band gap energy of the middle layer which is greater than a band gap energy of the lower layer.

20. The color image sensor structure of claim 19, wherein the upper layer absorbs wavelengths of light corresponding to a blue sub-band of a visible spectrum, the middle layer absorbs wavelengths of light corresponding to a green sub-band of the visible spectrum; and the lower layer absorbs wavelengths of light corresponding to a red sub-band of the visible spectrum.
